(19) United States
(12) Patent Application Publication
(10) Pub. No.: US 2020/0051790 A1
(43) Pub. Date: Feb. 13, 2020

(54) PRESSURE CONTROL RING, PLASMA PROCESSING APPARATUS INCLUDING THE SAME AND METHOD OF MANUFACTURING SEMICONDUCTOR DEVICE

(71) Applicant: Samsung Electronics Co., Ltd., Suwon-si (KR)

(72) Inventors: Kyu-Chul SHIM, Hwaseong-si (KR); Min-Kyu KANG, Hwaseong-si (KR); Bum-Soo KIM, Incheon (KR); Yong-Soo KIM, Seoul (KR); Hee-Jung KIM, Hwaseong-si (KR); Dae-Gyu BAN, Hwaseong-si (KR); Kyoung-Soo LEE, Incheon (KR); Jong-Sang LEE, Seoul (KR); Hyo-Il CHOI, Hwaseong-si (KR)

(21) Appl. No.: 16/252,875

(22) Filed: Jan. 21, 2019

(30) Foreign Application Priority Data
Aug. 8, 2018 (KR) 10-2018-0092625

(51) Int. Cl. H01J 37/32; H01L 21/683; H01L 21/67; C23C 16/50; C23C 16/44

(52) U.S. Cl. CPC H01J 37/32449; H01L 21/6831; H01J 37/32715; H01J 2237/182; C23C 16/50; C23C 16/4412; H01L 21/67017

(57) ABSTRACT

A plasma processing apparatus includes a plasma chamber, an electrostatic chuck disposed in the plasma chamber and a pressure control ring disposed in the plasma chamber. The pressure control ring includes a body surrounding an electrostatic chuck in a plan view, an exhaust part disposed in a portion of the body along a first direction, the exhaust part configured to induce a flow of gas in the plasma chamber toward the first direction in a plan view, and a blocking part disposed in another portion of the body along a second direction perpendicular to the first direction in a plan view, the blocking part configured to block the flow of the gas in the second direction.

### CROSS-REFERENCE TO RELATED APPLICATION

This application claims priority under 35 U.S.C. § 119 to Korean Patent Application No. 10-2018-0092625 filed on Aug. 8, 2018 in the Korean Intellectual Property Office, the disclosure of which is hereby incorporated by reference in its entirety.

### BACKGROUND

### Technical Field

Example embodiments of the present disclosure relate to a pressure control ring and a plasma processing apparatus including the same. For example, the present disclosure relates to a pressure control ring for controlling air flow in a plasma chamber and a plasma processing apparatus including the same. The present disclosure also relates to a method of manufacturing a semiconductor device using the apparatus and/or the pressure control ring.

### Discussion of Related Art

In general, a plasma processing apparatus is classified into a capacitively coupled plasma (CCP) type and an inductively coupled plasma (ICP) type.

A CCP processing apparatus includes a plasma chamber, a shower head in an upper space of the plasma chamber to introduce a process gas into the plasma chamber, an electrostatic chuck in a lower space of the plasma chamber to support a substrate, a pressure control ring surrounding the electrostatic chuck, and a vacuum pump providing vacuum in the plasma chamber through the pressure control ring.

A pressure control ring includes a plurality of slits for exhausting reaction by-products generating during a process. The plurality of slits are radially arranged across an entirety of the pressure control ring. Air flow including a process gas and the reacting by-products in the plasma chamber radially moves by the vacuum provided through the radial slits.

On the other hand, patterns formed on the substrate supported by the electrostatic chuck may extend in one direction. Among the radial air flow, the air flow moving in a direction parallel to an extension direction of the patterns easily flows through gaps between the patterns. However, among the radial air flow, the air flow moving in a direction perpendicular to the extension direction of the patterns collides with the patterns. Thus, the reaction by-products colliding with the patterns may not be exhausted out of the plasma chamber through the pressure control ring but may be continuously collected on surfaces of the patterns, thus causing defects in the patterns.

### SUMMARY

According to some example embodiments of the inventive concepts, a plasma processing apparatus may include a plasma chamber, an electrostatic chuck disposed in the plasma chamber, and a pressure control ring disposed in the plasma chamber. The pressure control ring may include a body surrounding an electrostatic chuck in a plan view, an exhaust part disposed in a portion of the body along a first direction, the exhaust part configured to induce a flow of gas in the plasma chamber toward the first direction, and a blocking part disposed in another portion of the body along a second direction perpendicular to the first direction in a plan view, the blocking part configured to block the flow of the gas in the second direction.

According to some example embodiments of the inventive concepts, a plasma processing apparatus may include a plasma chamber, and a pressure control ring being in the plasma chamber and including an exhaust part and a blocking part. The exhaust part may be configured to induce a flow of gas in the plasma chamber toward a first direction. The blocking part may be configured to block the flow of gas in a second direction perpendicular to the first direction.

According to some example embodiments of the inventive concepts, a plasma processing apparatus may include a plasma chamber, a shower head disposed in an upper space in the plasma chamber, the shower head configured to introduce a process gas into the plasma chamber, an electrostatic chuck disposed in a lower space in the plasma chamber, the electrostatic chuck configured to support a substrate, and a pressure control ring disposed adjacent to the electrostatic chuck. The pressure control ring may include a body surrounding the electrostatic chuck in a plan view, an exhaust part in the body, the exhaust part configured to induce a flow of a process gas and reaction by-products in the plasma chamber toward a first direction, the exhaust part including two sub-parts opposite each other, and a blocking part in the body, the blocking part configured to block the flow of the process gas and the reaction by-products in a second direction perpendicular to the first direction, wherein the blocking part includes two sub-parts opposite each other.

### BRIEF DESCRIPTION OF THE DRAWINGS

FIG. 1 is a cross-sectional view illustrating a plasma processing apparatus including a pressure control ring according to some example embodiments.

FIG. 2 is an enlarged plan view of the pressure control ring of FIG. 1 according to some example embodiments.

FIG. 3 is an enlarged perspective view of slits of the pressure control ring of FIG. 2 according to some example embodiments.

FIG. 4 is a plan view illustrating a flow of gas and/or by-products induced by the pressure control ring of FIG. 2.

FIG. 5 is a plan view illustrating a pressure control ring according to some example embodiments.

FIG. 6 is a plan view illustrating a pressure control ring according to some example embodiments.

### DETAILED DESCRIPTION OF THE EMBODIMENTS

Various example embodiments will now be described more fully with reference to the accompanying drawings in which some example embodiments are shown. However, the inventive concepts may be embodied in many different forms and should not be construed as limited to only those example embodiments set forth herein.

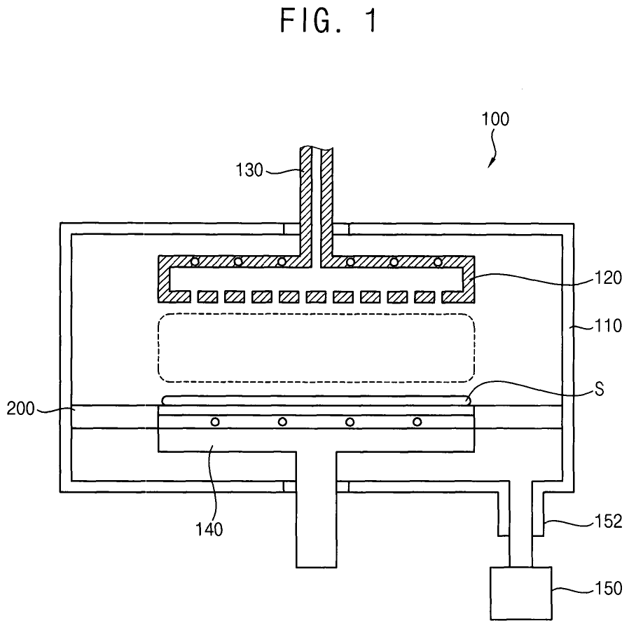

FIG. 1 is a cross-sectional view illustrating a plasma processing apparatus including a pressure control ring according to some example embodiments.

Referring to FIG. 1, a plasma processing apparatus 100 may include a plasma chamber 110, a shower head 120, a gas line 130, an electrostatic chuck 140, a vacuum pump 150, and a pressure control ring 200.

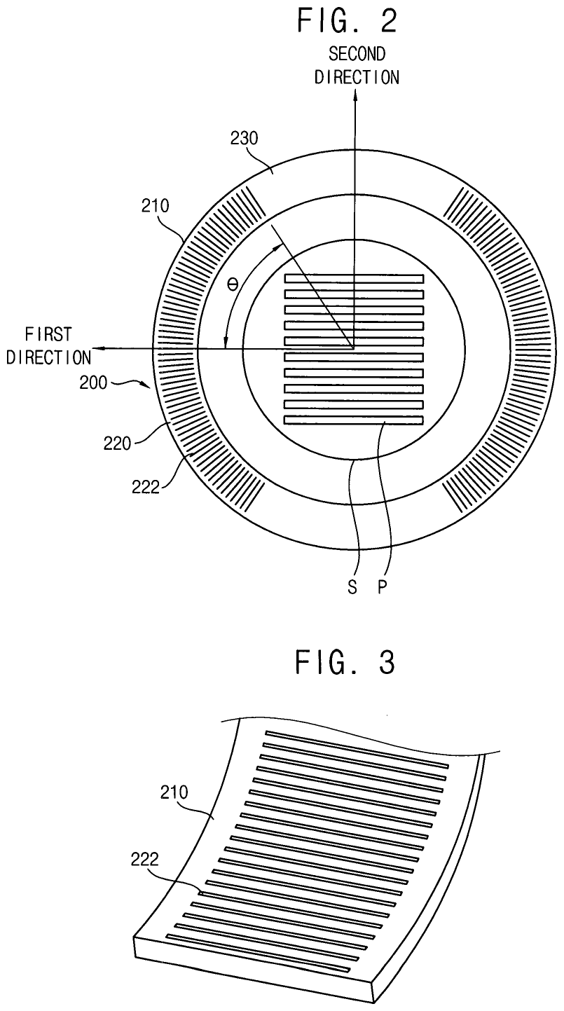

The plasma processing apparatus 100 may be a capacitively coupled plasma processing apparatus. The plasma processing apparatus 100 may be a deposition apparatus for forming a film on a substrate S using plasma or an etch apparatus for etching a film formed on the substrate S using plasma to form patterns (see, e.g., P of FIG. 2).

The plasma chamber 110 may have an internal space to receive the substrate S. The plasma chamber 110 may have a radial structure to improve uniformity of a layer or a pattern of a highly integrated semiconductor device. As shown in FIG. 2, the patterns P formed on the substrate S may extend in a first direction. Thus, as shown in FIG. 2, gaps formed between the patterns P may be arranged in a second direction perpendicular to the first direction.

The shower head 120 may be disposed in an upper space in the plasma chamber 110. The shower head 120 may include a plurality of injection holes for injecting a process gas into the plasma chamber 110. The shower head 120 may be connected to a high-frequency power supply, such that the shower head 120 may function as an upper electrode.

The gas line 130 may be connected to the shower head 120. The process gas may be supplied to the shower head 120 through the gas line 130. When the plasma processing apparatus 100 is the deposition apparatus, the process gas may include a deposition gas. When the plasma processing apparatus 100 is the etch apparatus, the process gas may include an etch gas.

The electrostatic chuck 140 may be disposed in a lower space in the plasma chamber 110. The substrate S may be disposed/fixed onto an upper surface of the electrostatic chuck 140. The electrostatic chuck 140 may be connected to the high-frequency power supply, and thus may function as a lower electrode.

The high-frequency power may be applied from the shower head 120 and the electrostatic chuck 140 to the process gas introduced into the plasma chamber 110 through the shower head 120, such that plasma may be generated in the plasma chamber 110. The plasma may be applied to the substrate S, such that a film may be deposited on the substrate S or a film on the substrate S may be etched to form the patterns (see, e.g., P of FIG. 2). During the deposition processor or the etch process, reaction by-products may be generated.

The vacuum pump 150 may provide vacuum in the plasma chamber 110. The vacuum pump 150 may be connected to the plasma chamber 110 through an exhaust line 152 connected to a lower portion/surface of the plasma chamber 110. The reaction by-products generated during the process may be exhausted from the plasma chamber 110 through the exhaust line 152 by the vacuum provided from the vacuum pump 150. The exhaust line 152 and vacuum pump 150 may form a vacuum exhaust system.

The pressure control ring 200 may have a shape surrounding the electrostatic chuck 140, e.g., in a plan view. In certain embodiments, the pressure control ring 200 may include an inner circumferential surface, e.g., an inner circular surface, close to an outer circumferential surface of the electrostatic chuck 140 and an outer circumferential surface close to the inner sidewall of the plasma chamber 110. The vacuum pump 150 may evacuate the plasma chamber 110 through the pressure control ring 200. A vacuum degree in the plasma chamber 110 may be controlled by the pressure control ring 200, such that an internal pressure of the plasma chamber 110 may be adjusted. Since the plasma chamber 110 is evacuated through the pressure control ring 200, a flow of a process gas and/or a flow of the reaction by-products may be controlled in the plasma chamber 110, e.g., by the vacuum pump 150.

FIG. 2 is an enlarged plan view of the pressure control ring of FIG. 1 according to some example embodiments. FIG. 3 is an enlarged perspective view of slits of the pressure control ring of FIG. 2 according to some example embodiments.

Referring to FIGS. 2 and 3, the pressure control ring 200 may include a body 210 of ring shape. The body 210 may include an exhaust part 220 and a blocking part 230.

The plasma chamber 110 may be evacuated through the exhaust part 220. For example, the reaction by-products may be removed/exhausted through the exhaust part 220. The exhaust part 220 may be positioned in the first direction that is the extension direction of the patterns P. For example, the exhaust part 220 may include two sub-sections arranged in the first direction. For example, the two sub-sections of the exhaust part 220 may be disposed at opposite ends of the pressure control ring 200 with the electrostatic chuck 140 being disposed therebetween in a plan view, and with the patterns P extending in the first direction between the opposite ends of the pressure control ring 200.

However, in the example of FIG. 2, the plasma chamber 110 is not evacuated through the blocking part 230. For example, the blocking part 230 may not allow the reaction by-products to pass therethrough. The blocking part 230 may be positioned in the second direction perpendicular to the extension direction of the patterns P. For example, the blocking part 230 may include two sub-sections arranged in the second direction and may be between the sub-sections of the exhaust part 220. For example, the two sub-sections of the blocking part 230 may be disposed at opposite ends of the pressure control ring 200 with the electrostatic chuck 140 being disposed therebetween in a plan view. The blocking part 230 may correspond to the remainder of the body 210 other than the exhaust part 220. For example, in one embodiment, the two sub-sections of the exhaust part 220 and the two sub-sections of the blocking part 230 are disposed alternately along the pressure control ring 200 in a rotational direction in a plan view.

As an example, the exhaust part 220 may include a plurality of slits 222. For example, the slits 222 may be arranged along a circumference direction of the body 210. In an embodiment, the slits 222 may be formed in a portion of the body 210 disposed in the first direction to form the exhaust part 220. However, the slits 222 may not be formed in the blocking part 230. For example, the blocking part 230 may have a solid form throughout the blocking part 230. Thus, the vacuum may be provided in the plasma chamber 110 through the slits 222, and the reaction by-products may be exhausted out of the plasma chamber 110 through the slits 222. For example, the gas/by-product flow in the plasma chamber 110 may mainly flow in the first direction, and there may be no substantial flow of gas/by-product in the second direction.

As an example, the slits 222 may radially extend from the center of the body 210. For example, the slits 222 may extend in a radius direction of the body 210. The slits 222 may be arranged at substantially the same distance with respect to each other. For example, distances between adjacent slits 222 may be the same throughout the slits 222. In some embodiments, distances between the slits 222 may not be the same. For example, the slits 222 may be disposed at the same distance from a center of the body 210, e.g., the center of the electrostatic chuck 140, in a plan view.

An outermost slit of the slits 222 may be disposed at an acute angle θ with respect to a diameter line in the first direction. For example, the acute angle θ may be an angle formed by a first line extending in the first direction and a second line crossing the first line at the center of the pressure control ring 200 and/or the electrostatic chuck 140 in a plan view. For example, the acute angle θ may range from 45° to 60°. When the acute angle θ is less than 60°, a ratio of an area of the slits 222 with respect to a total area of the pressure control ring 200 (e.g., an aperture ratio of the pressure control ring 200) may be relatively small. In this case, the exhaust effect of the reaction by-products may be decreased. When the acute angle θ is above 60°, the aperture ratio of the pressure control ring 200 may be relatively great. In this case, some of the slits 222 may be positioned adjacent to a location in the second direction, and thus a function of the blocking part 230 may be degraded. For example, the gas/by-products in the plasma chamber 110 may partly flow in the second direction. For example, the outermost slit of the slits 222 may be disposed at the angle θ of 45° to 60° with respect to the diameter line in the first direction. Certain slits 222, such as central slits, may extend lengthwise parallel to the first direction, and thus may extend lengthwise in the same direction as the patterns P. Items described herein as extending lengthwise extend in a length direction and have a length and width, where the length is greater than the width.

Terms such as “same,” “equal, or “parallel,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes.

As shown in FIGS. 2 and 3, according to some embodiments, the exhaust part 220 includes two first pie-slice sections of the body 210 opposite each other in the first direction. Each first pie-slice section includes a plurality of slits 222, or slit-shaped openings. Each pie-slice section may cover an angle of at least 90°, which angle may be between, for example, 90° and 120°. However, other angles may be used. As shown in FIGS. 2 and 3, the blocking part 230 includes two second pie-slice sections of the body 210 opposite each other in the second direction. In some embodiments, each second pie-slice section extends from one of the first pie-slice sections to the other of the first pie-slice sections and each blocking part includes no openings, or no slit-shape openings. For example, two pie-shaped sections, or sub-parts, of the exhaust part 220 and the two pie-shaped sections, or sub-parts, of the blocking part 230 may include the entire body 210 from a top-down view. According to some embodiments, within each first pie-slice section, the plurality of slit-shaped openings are separated from each other by a constant pitch and have the same width in a radial direction. Each of the second pie-slice sections may cover an angle of at least 60°, and in some embodiments, between 60° and 90°. For example, each of the first pie-slice sections may cover an angle between 90° and 120°, and the two second pie-slice sections may comprise the remainder of the radial circumference of the body 210.

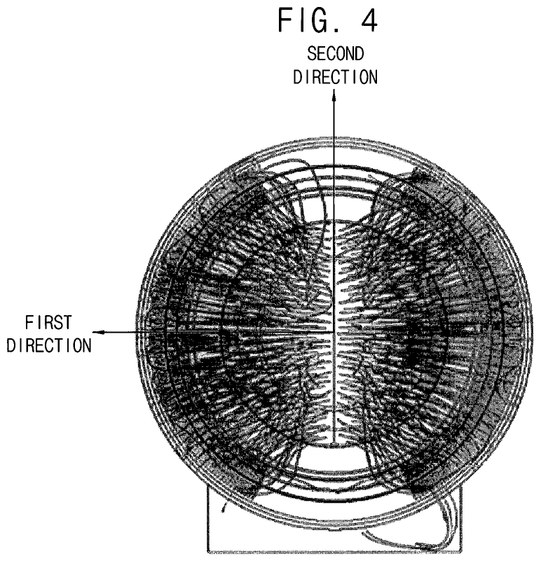

FIG. 4 is a plan view illustrating a flow of gas/by-product induced by the pressure control ring of FIG. 2.

Referring to FIG. 4, since the slits 222 are formed in the exhaust part 220 of the body 210, and there is no slit in the blocking part 230 of the body 210, the gas/by-product may not flow in the second direction but may mainly flow in the first direction.

For example, the reaction by-products may mainly flow in the first direction, and thus may be effectively exhausted out of the plasma chamber 110 through the gaps between the patterns P extending in the first direction. However, since the reaction by-products hardly flow in the second direction, an amount of the reaction by-products collected on the patterns P may be highly reduced.

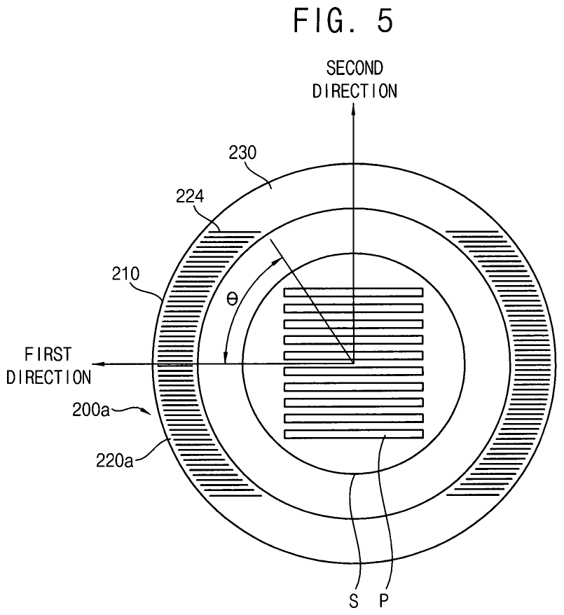

FIG. 5 is a plan view illustrating a pressure control ring according to some example embodiments.

A pressure control ring 200a according to some example embodiments may include the same elements as the pressure control ring 200 shown in FIG. 2, except for an exhaust part 220a.

Referring to FIG. 5, the exhaust part 220a of the pressure control ring 200a may include a plurality of slits 224. Each of the slits 224 may extend lengthwise in a direction parallel to the first direction that is the extension direction of the patterns P. Thus, a direction of a flow of the reaction by-products may be induced toward the first direction by evacuation through the slits 224.

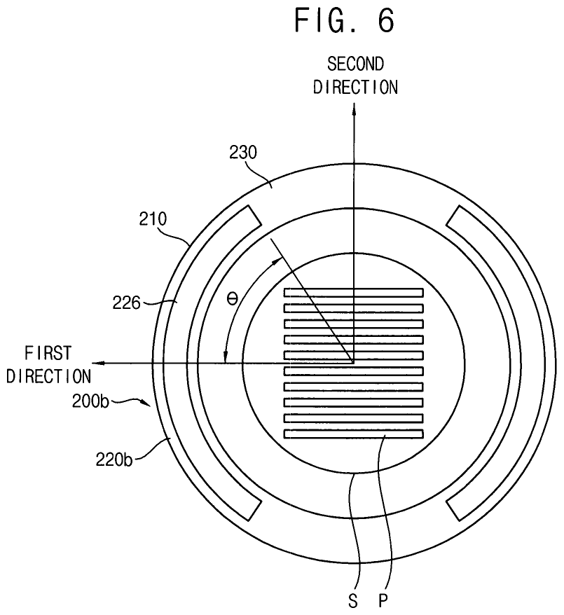

FIG. 6 is a plan view illustrating a pressure control ring according to some example embodiments.

A pressure control ring 200b according to some example embodiments may include the same elements as the pressure control ring 200 shown in FIG. 2, except for an exhaust part 220b.

Referring to FIG. 6, the exhaust part 220b of the pressure control ring 200b may include one exhaust hole 226 per each sub-section. The exhaust hole 226 may be formed in a portion of the body 210 corresponding to the portion of the body 210 in which the slits 222 shown in FIG. 2 are disposed. For example, a first angle formed between a first line extending in the first direction and a second line crossing the first line at the center of the pressure control ring 200b and/or the electrostatic chuck 140 and contacting the outermost point of the exhaust hole 226 in a plan view may be equal to or less than 60°. For example, the exhaust hole 226 may be formed continuously within the first angle.

A structure of the pressure control rings 200, 200a, and 200b according to example embodiments disclosed above may be applied to an exhaust part of a symmetrical type liner of an inductively coupled plasma (ICP) processing apparatus. For example, each of the pressure control rings 200, 200a and 200b disclosed above may be applied to an ICP processing apparatus as a pressure control ring.

According to example embodiments disclosed above, as the exhaust part is disposed only in the first direction that is the extension direction of the patterns on the substrate, the flow of the gas/by-products in the second direction perpendicular to the extension direction of the patterns may be blocked/reduced. Thus, the gas/by-products may be inhibited from colliding with the patterns, such that the gas/by-products may be easily flow. For example, the reaction by-products may be prevented from being accumulated on the surfaces of the patterns. For example, the reaction by-products may be effectively exhausted through the exhaust part of the pressure control ring.

According to an embodiment of the present disclosure, a method of manufacturing a semiconductor device may include that a substrate S is provided on an electrostatic chuck 140 disposed in a plasma chamber 110 of a plasma processing apparatus 100. An insulator layer or a conductive layer may be formed on the substrate S by a deposition process. After forming the insulator layer or the conductive layer on the substrate S, reaction gas used to form the insulator layer or the conductive layer and/or by-products generated during the deposition process may be removed from the plasma chamber 110 by a vacuum pump 150 included in the plasma processing apparatus 100. The plasma processing apparatus 100 may be one of the embodiments disclosed above. When the substrate S is provided on the electrostatic chuck 140 and during the process that forms reaction gas and by-products, the substrate S is disposed so that patterns on the substrate extend in the same direction as some of the slits formed in the exhaust part of the pressure controlling ring.

According to some embodiments, a method of manufacturing a semiconductor device may include that a substrate S is disposed on an electrostatic chuck 140 disposed in a plasma chamber 110 of a plasma processing apparatus 100. The substrate S may include a conductive layer or an insulator layer formed on the substrate S. The conductive layer or the insulator layer may be etched to form a conductive pattern or an insulator pattern on the substrate S. After forming the conductive pattern or the insulator pattern on the substrate S by the etching process, reaction gas used for the etching process and/or by-products generated during the patterning process may be removed from the plasma chamber 110 by vacuum pump 150 included in the plasma processing apparatus 100. The plasma processing apparatus 100 may be one of the embodiments disclosed above. When the substrate S is disposed on the electrostatic chuck 140 and during the removal of the reaction gas or by-products, the substrate S is disposed so that patterns being formed on the substrate extend in the same direction as some of the slits formed in the exhaust part of the pressure controlling ring.

In the above manner, a substrate having patterns formed thereon may be disposed on an electrostatic chuck and oriented in a first manner to have a majority of the patterns extending lengthwise in the first direction. The plasma processing apparatus is configured to remove gases and/or reaction by-products through the slit-shaped openings while the substrate is oriented in the first manner. For example, computer equipment of the plasma processing apparatus may be programmed such that the majority of patterns of the substrate are formed in the first direction during a process, and the vacuum exhaust system is turned on during or after the process to remove reaction gases and/or by-products formed during the process.

In certain embodiments, the substrate S formed with the conductive pattern and/or the insulator pattern may be diced into a plurality of semiconductor chips. The semiconductor chips may be packaged to form a semiconductor device.

While the present inventive concepts have been particularly shown and described with reference to example embodiments thereof, it will be understood by those of ordinary skill in the art that various changes in form and details may be made therein without departing from the spirit and scope of the present disclosure as defined by the following claims.

What is claimed is:

1. A plasma processing apparatus comprising:
a plasma chamber;
an electrostatic chuck disposed in the plasma chamber; and
a pressure control ring disposed in the plasma chamber,
wherein the pressure control ring comprises:
a body surrounding an electrostatic chuck in a plan view;
an exhaust part disposed in a portion of the body along a first direction, the exhaust part configured to induce a flow of gas in the plasma chamber toward the first direction; and
a blocking part disposed in another portion of the body along a second direction perpendicular to the first direction in a plan view, the blocking part configured to block the flow of the gas in the second direction.

2. The plasma processing apparatus of claim 1, wherein:
the exhaust part includes two first pie-slice sections of the body opposite each other in the first direction, each first pie-slice section including a plurality of slit-shaped openings; and
the blocking part includes two second pie-slice sections of the body opposite each other in the second direction, each second pie-slice section extending from one of the first pie-slice sections to the other of the first pie-slice sections, each blocking part including no openings.

3. The plasma processing apparatus of claim 2, wherein:
within each first pie-slice section, the plurality of slit-shaped openings are separated from each other by a constant pitch and have the same width in a radial direction.

4. The plasma processing apparatus of claim 2, wherein:
within each first pie-slice section, at least two of the plurality of slit-shaped openings are parallel to the first direction.

5. The plasma processing apparatus of claim 2, wherein each of the first pie-slice sections covers an angle of at least 90°, and each of the second pie-slice sections covers an angle of at least 60°.

6. The plasma processing apparatus of claim 5, wherein each of the first pie-slice sections covers an angle between 90° and 120° of a radial circumference of the body, and the two second pie-slice sections covers the remainder of the radial circumference of the body.

7. The plasma processing apparatus of claim 2, wherein the plurality of slit-shaped openings radially extend from a center of the body in a plan view.

8. The plasma processing apparatus of claim 7, wherein at least one slit-shaped opening in each of the first pie-slice sections is parallel to the first direction.

9. The plasma processing apparatus of claim 2, further comprising:
a substrate having patterns formed thereon, the substrate disposed on the electrostatic chuck and oriented in a first manner to have a majority of the patterns extending lengthwise in the first direction,
wherein the plasma processing apparatus is configured to remove gases and/or reaction by-products through the slit-shaped openings while the substrate is oriented in the first manner.

10. A plasma processing apparatus comprising:
a plasma chamber; and
a pressure control ring being in the plasma chamber and including an exhaust part and a blocking part,
wherein the exhaust part is configured to induce a flow of gas in the plasma chamber toward a first direction, and
wherein the blocking part is configured to block the flow of gas in a second direction perpendicular to the first direction.

11. The plasma processing apparatus of claim 10, wherein the exhaust part includes two sub-sections arranged in the first direction to be opposite each other, and
wherein the blocking part includes two sub-sections arranged in the second direction, each formed between the sub-sections of the exhaust part.

12. The plasma processing apparatus of claim 11, wherein the exhaust part includes a plurality of slit-shaped openings radially extending with respect to a center of the pressure control ring.

13. The plasma processing apparatus of claim 12, wherein the blocking part does not include any openings.

14. The plasma processing apparatus of claim 11, wherein each sub-section of the exhaust part includes a plurality of slits extending in a direction parallel to the first direction.

15. A plasma processing apparatus comprising:
a plasma chamber;
a shower head disposed in an upper space in the plasma chamber, the shower head configured to introduce a process gas into the plasma chamber;
an electrostatic chuck disposed in a lower space in the plasma chamber, the electrostatic chuck configured to support a substrate; and
a pressure control ring disposed adjacent to the electrostatic chuck,
wherein the pressure control ring comprises:
a body surrounding the electrostatic chuck in a plan view,
an exhaust part in the body, the exhaust part configured to induce a flow of a process gas and reaction by-products in the plasma chamber toward a first direction, the exhaust part including two sub-parts opposite each other; and
a blocking part in the body, the blocking part configured to block the flow of the process gas and the reaction by-products in a second direction perpendicular to the first direction, wherein the blocking part includes two sub-parts opposite each other.

16. The plasma processing apparatus of claim 15, further comprising:
an exhaust line connected to a lower portion of the plasma chamber, the exhaust line configured to exhaust the reaction by-products; and
a vacuum pump configured to evacuate the plasma chamber through the exhaust line and the exhaust part.

17. The plasma processing apparatus of claim 15, wherein the exhaust part includes a plurality of slit-shaped openings radially extending with respect to a center of the body.

18. The plasma processing apparatus of claim 17, wherein two sub-parts of the exhaust part and the two sub-parts of the blocking part include the entire body from a top-down view.

19. The plasma processing apparatus of claim 15, wherein each sub-part of the exhaust part includes a plurality of slits extending in a direction parallel to the first direction.

20. The plasma processing apparatus of claim 15, wherein each sub-part of the exhaust part includes a plurality of slit-shaped openings separated by a constant pitch and having the same width in a radial direction, and each sub-part of the blocking part includes no slit-shaped openings.
